(19) United States
(12) Patent Application Publication
(10) Pub. No.: US 2023/0062770 A1
(43) Pub. Date: Mar. 2, 2023

(54) HEATING MEMBER AND SUBSTRATE TREATING APPARATUS

(71) Applicant: SEMES CO., LTD., Cheonan-si (KR)

(72) Inventors: Dong Hyuk SEO, Pyeongtaek-si (KR); Myung Hwan OH, Yongin-si (KR); Bong Kuk KIM, Cheonan-si (KR); Sung Yong LEE, Yongin-si (KR); Min Jun KIM, Cheonan-si (KR)

(73) Assignee: SEMES CO., LTD., Cheonan-si (KR)

(21) Appl. No.: 17/896,614

(22) Filed: Aug. 26, 2022

(30) Foreign Application Priority Data
Aug. 31, 2021 (KR) 10-2021-0115641

(51) Int. Cl. H01L 21/67

(52) U.S. Cl. CPC H01L 21/67103; H01L 21/67248; H05B 3/283

(57) ABSTRACT

The inventive concept relates to a heating member for heating a substrate. In an embodiment, the heating member includes a heater plate having at least one heating element bonded thereto, a connecting plate having a first space formed therein in which the heating element is accommodated, and a control plate having a control element bonded thereto, the control element being electrically connected with the heating element to control the heating element.

### CROSS-REFERENCE TO RELATED APPLICATIONS

A claim for priority under 35 U.S.C. § 119 is made to Korean Patent Application No. 10-2021-0115641 filed on Aug. 31, 2021, in the Korean Intellectual Property Office, the entire contents of which are hereby incorporated by reference.

### BACKGROUND

Embodiments of the inventive concept described herein relate to a heating member for heating a substrate and a substrate treating apparatus including the same.

Various processes, such as deposition, photolithography, etching, cleaning, and the like, are performed to manufacture semiconductor devices. In the respective processes, processing liquids are dispensed onto a substrate through nozzles. Apparatuses for performing the processes may include heater systems for heating the processing liquids, the process spaces, the substrate, and the like.

FIG. 1 illustrates a heating member in the related art. The heating member in the related art is a heating member of a heating wire type in which electric wires are connected to joints of heating wires of a heater plate. According to the related art, as a heating zone to be controlled is divided, the number of electric wires is increased, and the entire volume of the electric wires is also increased. Therefore, there is a limitation in dividing the heating zone. Furthermore, because the heating wires of the heater plate and the electric wires are joined, losses according to lower air convection types differ from one another depending on the shapes of the electric wires. Accordingly, a difference in temperature between regions occurs. Moreover, stress is applied to the joints depending on the curvatures of the electric wires, and strong stress may cause damage to the joints. In addition, heat loss depending on conduction occurs in the portions to which the electric wires are joined, which causes a temperature imbalance.

### SUMMARY

Embodiments of the inventive concept provide a heating member and a substrate treating apparatus for efficiently treating a substrate.

Embodiments of the inventive concept provide a heating member and a substrate treating apparatus for precisely controlling a heating temperature of a substrate.

Embodiments of the inventive concept provide a heating member and a substrate treating apparatus for increasing a heating zone, compared to those in the related art.

Embodiments of the inventive concept provide a heating member and a substrate treating apparatus for making air convection under the heating member uniform, reducing a difference in temperature between regions, and solving a problem of stress in joints of electric wires, by removing the electric wires under the heating member.

The technical problems to be solved by the inventive concept are not limited to the aforementioned problems. Any other technical problems not mentioned herein will be clearly understood from the following description by those skilled in the art to which the inventive concept pertains.

According to an embodiment, a heating member includes a heater plate having at least one heating element bonded thereto, a connecting plate having a first space formed therein in which the heating element is accommodated, and a control plate having a control element bonded thereto, the control element being electrically connected with the heating element to control the heating element.

In an embodiment, the heating element may be bonded with a first metal pad and a second metal pad bonded to the heater plate.

In an embodiment, the connecting plate may have a first via hole and a second via hole formed around the first space.

In an embodiment, the first via hole may be connected with the first metal pad, and the second via hole may be connected with the second metal pad.

In an embodiment, the connecting plate may include a first circuit pattern electrically connected with a metallic material provided in the first via hole and a second circuit pattern electrically connected with a metallic material provided in the second via hole.

In an embodiment, in the control plate, a third via hole may be formed in a position corresponding to the first circuit pattern, and a fourth via hole may be formed in a position corresponding to the second circuit pattern.

In an embodiment, the control plate may include a third circuit pattern electrically connected with a metallic material provided in the third via hole and a fourth circuit pattern electrically connected with a metallic material provided in the fourth via hole, and the third circuit pattern and the fourth circuit pattern may be electrically connected with the control element.

In an embodiment, the heating element may be spaced apart from the control plate.

In an embodiment, the first space may include a plurality of first spaces, the heating element may include a plurality of heating elements, and the plurality of heating elements may be accommodated in the plurality of first spaces, respectively.

In an embodiment, the control element may include a plurality of control elements, the heating element may include a plurality of heating elements, and each of the control elements may be electrically connected with some of the plurality of heating elements.

In an embodiment, the control element may include a plurality of control elements, the heating element may include a plurality of heating elements, and the plurality of control elements may be electrically connected with the plurality of heating elements, respectively.

According to an embodiment, a substrate treating apparatus includes a chamber having a process space therein, a support unit that supports a substrate in the process space, and a heating member that is provided in the support unit and that heats the substrate. The heating member includes a heater plate having at least one heating element bonded thereto, a connecting plate having a first space formed therein in which the heating element is accommodated, and a control plate having a control element bonded thereto, the control element being electrically connected with the heating element to control the heating element.

In an embodiment, the heating element may be bonded with a first metal pad and a second metal pad bonded to the heater plate.

In an embodiment, the connecting plate may have a first via hole and a second via hole formed around the first space. The first via hole may be connected with the first metal pad, and the second via hole may be connected with the second metal pad.

In an embodiment, the connecting plate may include a first circuit pattern electrically connected with a metallic material provided in the first via hole and a second circuit pattern electrically connected with a metallic material provided in the second via hole.

In an embodiment, in the control plate, a third via hole may be formed in a position corresponding to the first circuit pattern, and a fourth via hole may be formed in a position corresponding to the second circuit pattern.

In an embodiment, the control plate may include a third circuit pattern electrically connected with a metallic material provided in the third via hole and a fourth circuit pattern electrically connected with a metallic material provided in the fourth via hole, and the third circuit pattern and the fourth circuit pattern may be electrically connected with the control element.

In an embodiment, the heating element may be spaced apart from the control plate.

In an embodiment, the first space may include a plurality of first spaces, the heating element may include a plurality of heating elements, and the plurality of heating elements may be accommodated in the plurality of first spaces, respectively.

According to an embodiment, a substrate treating apparatus includes a chamber having a process space therein, a support unit that supports a substrate in the process space, and a heating member that is provided in the support unit and that heats the substrate. The heating member includes a heater plate including a plurality of heating elements, each of which is bonded to the heater plate through a first metal pad and a second metal pad, a connecting plate in which a first via hole connected with the first metal pad and a second via hole connected with the second metal pad are formed, the connecting plate including a first circuit pattern electrically connected with a metallic material provided in the first via hole and a second circuit pattern electrically connected with a metallic material provided in the second via hole, wherein as many first spaces as the plurality of heating elements are formed in the connecting plate and the heating elements are accommodated in the first spaces, respectively, and a control plate in which a third via hole is formed in a position corresponding to the first circuit pattern and a fourth via hole is formed in a position corresponding to the second circuit pattern, the control plate including a third circuit pattern electrically connected with a metallic material provided in the third via hole and a fourth circuit pattern electrically connected with a metallic material provided in the fourth via hole, wherein the control plate has a plurality of control elements bonded thereto, each of which is electrically connected with the third circuit pattern and the fourth circuit pattern and controls a corresponding one of the heating elements.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a bottom view of a heating member in the related art;

FIG. 2 is a schematic perspective view illustrating a substrate treating apparatus according to an embodiment of the inventive concept;

FIG. 3 is a sectional view illustrating coating blocks and developing blocks of the substrate treating apparatus of FIG. 2;

FIG. 4 is a plan view illustrating the substrate treating apparatus of FIG. 2;

FIG. 5 is a view illustrating one example of a hand of a transfer unit of FIG. 4;

FIG. 6 is a schematic horizontal sectional view illustrating one example of heat treatment chambers of FIG. 4;

FIG. 7 is a front sectional view illustrating the heat treatment chamber of FIG. 6;

FIG. 8 is an exploded perspective view of a heating member according to an embodiment of the inventive concept;

FIG. 9 is a bottom view of a heater plate according to an embodiment of the inventive concept;

FIG. 10 is an enlarged sectional view illustrating a portion in which a heating element is provided in the heating member according to an embodiment of the inventive concept;

FIGS. 11A to 11F are views illustrating an assembly sequence of the heating member according to an embodiment of the inventive concept; and

FIG. 12 is an exploded perspective view of a heating unit including a control plate according to another embodiment of the inventive concept.

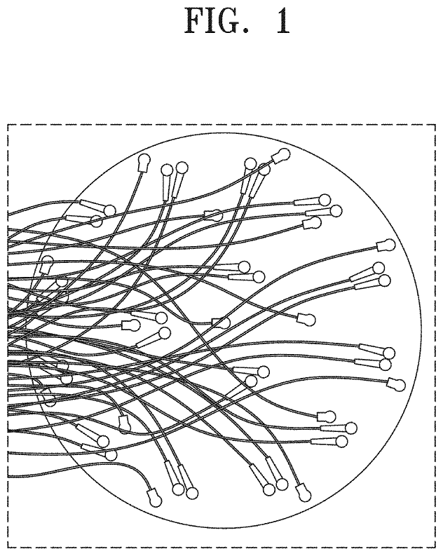

### DETAILED DESCRIPTION

Hereinafter, embodiments of the inventive concept will be described in detail with reference to the accompanying drawings such that those skilled in the art to which the inventive concept pertains can readily carry out the inventive concept. However, the inventive concept may be implemented in various different forms and is not limited to the embodiments described herein. Furthermore, in describing the embodiments of the inventive concept, detailed descriptions related to well-known functions or configurations will be omitted when they may make subject matters of the inventive concept unnecessarily obscure. In addition, components performing similar functions and operations are provided with identical reference numerals throughout the accompanying drawings.

The terms “include” and “comprise” in the specification are “open type” expressions just to say that the corresponding components exist and, unless specifically described to the contrary, do not exclude but may include additional components. Specifically, it should be understood that the terms “include”, “comprise”, and “have”, when used herein, specify the presence of stated features, integers, steps, operations, components, and/or parts, but do not preclude the presence or addition of one or more other features, integers, steps, operations, components, parts, and/or groups thereof.

The terms such as first, second, and the like may be used to describe various components, but the components should not be limited by the terms. The terms may be used only for distinguishing one component from others. For example, without departing the scope of the inventive concept, a first component may be referred to as a second component, and similarly, the second component may also be referred to as the first component.

The terms of a singular form may include plural forms unless otherwise specified. Furthermore, in the drawings, the shapes and dimensions of components may be exaggerated for clarity of illustration.

In the entire specification, the terms, component “˜unit” and component “˜module” refer to software components or hardware components such as an FPGA or an ASIC, and perform at least one function or operation. It should be, however, understood that the component “˜unit” and the component “˜module” are not limited to software or hardware components. The component “˜unit” and the component “˜module” may be implemented in storage media that can be designated by addresses. The component “˜unit” and the component “˜module” may also be configured to regenerate one or more processors.

For example, the component “˜unit” and the component “˜module” may include various types of components (e.g., software components, object-oriented software components, class components, and task components), processes, functions, attributes, procedures, sub-routines, segments of program codes, drivers, firmware, micro-codes, circuit, data, data base, data structures, tables, arrays, and variables. Functions provided by a component, the component “˜unit,” and the component “˜module” may be separately performed by a plurality of components, components “˜units,” and components “˜modules” and may also be integrated with other additional components.

Hereinafter, a substrate treating apparatus according to an embodiment of the inventive concept will be described.

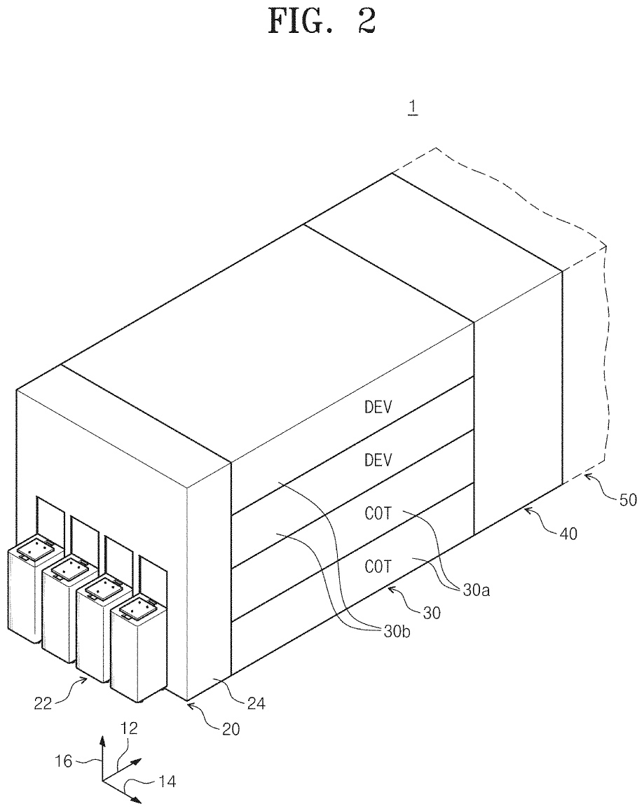

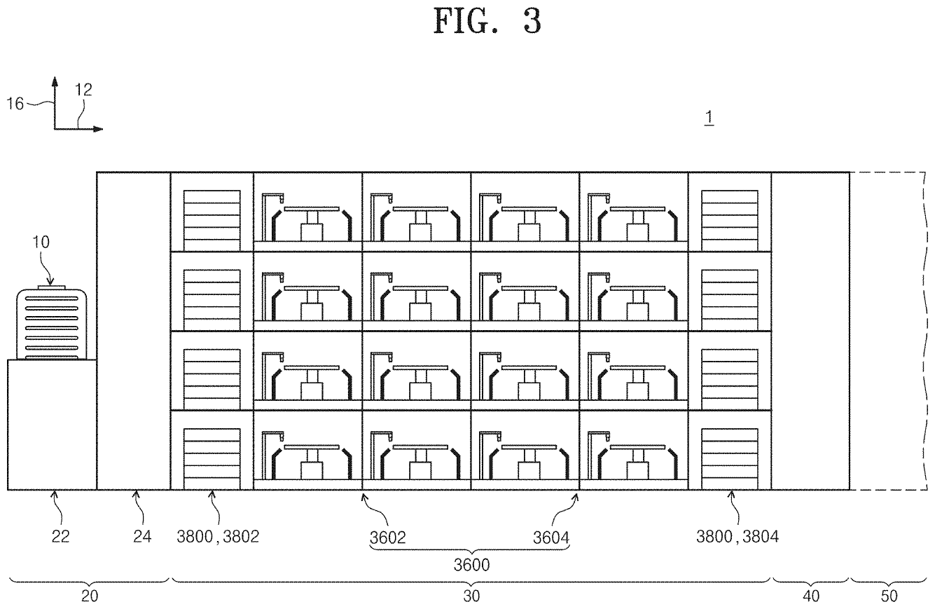

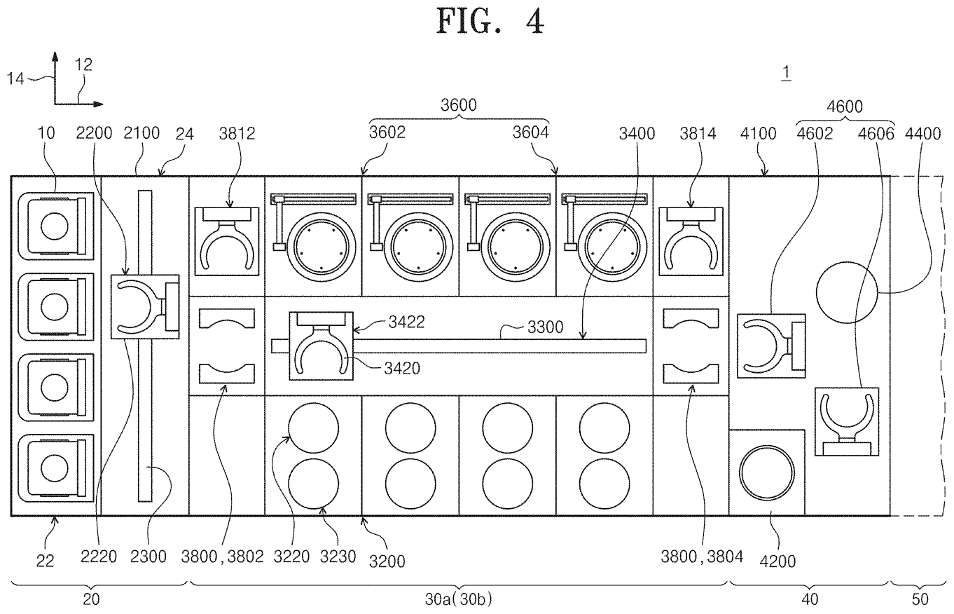

FIG. 2 is a schematic perspective view illustrating the substrate treating apparatus according to an embodiment of the inventive concept. FIG. 3 is a sectional view illustrating coating blocks and developing blocks of the substrate treating apparatus of FIG. 2. FIG. 4 is a plan view illustrating the substrate treating apparatus of FIG. 2.

Referring to FIGS. 2 to 4, the substrate treating apparatus 1 includes an index module 20, a treating module 30, and an interface module 40. According to an embodiment, the index module 20, the treating module 30, and the interface module 40 are sequentially arranged in a row. Hereinafter, a direction in which the index module 20, the treating module 30, and the interface module 40 are arranged is referred to as an X-axis direction 12, a direction perpendicular to the X-axis direction 12 when viewed from above is referred to as a Y-axis direction 14, and a direction perpendicular to both the X-axis direction 12 and the Y-axis direction 14 is referred to as a Z-axis direction 16.

The index module 20 transfers substrates W from carriers 10 having the substrates W received therein to the treating module 30 and places the completely treated substrates W in the carriers 10. The lengthwise direction of the index module 20 is parallel to the Y-axis direction 14. The index module 20 includes load ports 22 and an index frame 24. The load ports 22 are located on the opposite side to the treating module 30 with respect to the index frame 24. The carriers 10 having the substrates W received therein are placed on the load ports 22. The load ports 22 may be disposed in the Y-axis direction 14.

Airtight carriers 10 such as front open unified pods (FOUPs) may be used as the carriers 10. The carriers 10 may be placed on the load ports 22 by a transfer unit (not illustrated), such as an overhead transfer, an overhead conveyor, or an automatic guided vehicle, or by an operator.

An index robot 2200 is provided in the index frame 24. A guide rail 2300, the lengthwise direction of which is parallel to the Y-axis direction 14, is provided in the index frame 24. The index robot 2200 is movable on the guide rail 2300. The index robot 2200 includes hands 2220 on which the substrates W are placed, and the hands 2220 are movable forward and backward, rotatable about an axis facing in the Z-axis direction 16, and movable in the Z-axis direction 16.

The treating module 30 performs a coating process and a developing process on the substrates W. The treating module 30 includes the coating blocks 30a and the developing blocks 30b. The coating blocks 30a perform the coating process on the substrates W, and the developing blocks 30b perform the developing process on the substrates W. The coating blocks 30a are stacked on each other. The developing blocks 30b are stacked on each other. According to the embodiment of FIG. 2, two coating blocks 30a and two developing block 30b are provided. The coating blocks 30a may be disposed under the developing blocks 30b. According to an embodiment, the two coating blocks 30a may perform the same process and may have the same structure. Furthermore, the two developing blocks 30b may perform the same process and may have the same structure.

Referring to FIG. 4, each of the coating blocks 30a includes heat treatment chambers 3200, a transfer chamber 3400, liquid treatment chambers 3600, and buffer chambers 3800. The heat treatment chambers 3200 perform a heat treatment process on the substrates W. The heat treatment process may include a cooling process and a heating process. The liquid treatment chambers 3600 form liquid films on the substrates W by supplying a liquid onto the substrates W. The liquid films may be photoresist films or anti-reflection films. The transfer chamber 3400 transfers the substrates W between the heat treatment chambers 3200 and the liquid treatment chambers 3600 in the coating block 30a.

The transfer chamber 3400 is disposed such that the lengthwise direction thereof is parallel to the X-axis direction 12. A transfer unit 3420 is provided in the transfer chamber 3400. The transfer unit 3420 transfers the substrates W between the heat treatment chambers 3200, the liquid treatment chambers 3600, and the buffer chambers 3800. According to an embodiment, the transfer unit 3420 has a hand A on which a substrate W is placed, and the hand A is movable forward and backward, rotatable about an axis facing in the Z-axis direction 16, and movable in the Z-axis direction 16. A guide rail 3300, the lengthwise direction of which is parallel to the X-axis direction 12, is provided in the transfer chamber 3400. The transfer unit 3420 is movable on the guide rail 3300.

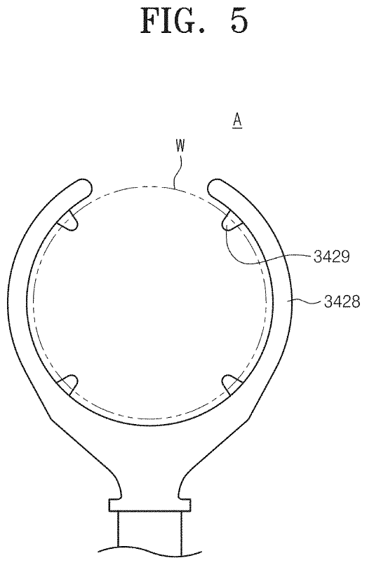

FIG. 5 is a view illustrating one example of the hand of the transfer unit of FIG. 4. Referring to FIG. 5, the hand A includes a base 3428 and support protrusions 3429. The base 3428 may have an annular ring shape, the circumference of which is partially curved. The base 3428 has an inner diameter greater than the diameter of the substrate W. The support protrusions 3429 extend inward from the base 3428. The support protrusions 3429 support an edge region of the substrate W. According to an embodiment, four support protrusions 3429 may be provided at equal intervals.

Referring again to FIGS. 3 and 4, a plurality of heat treatment chambers 3200 are provided. The heat treatment chambers 3200 are arranged in the first direction 12. The heat treatment chambers 3200 are located on one side of the transfer chamber 3400.

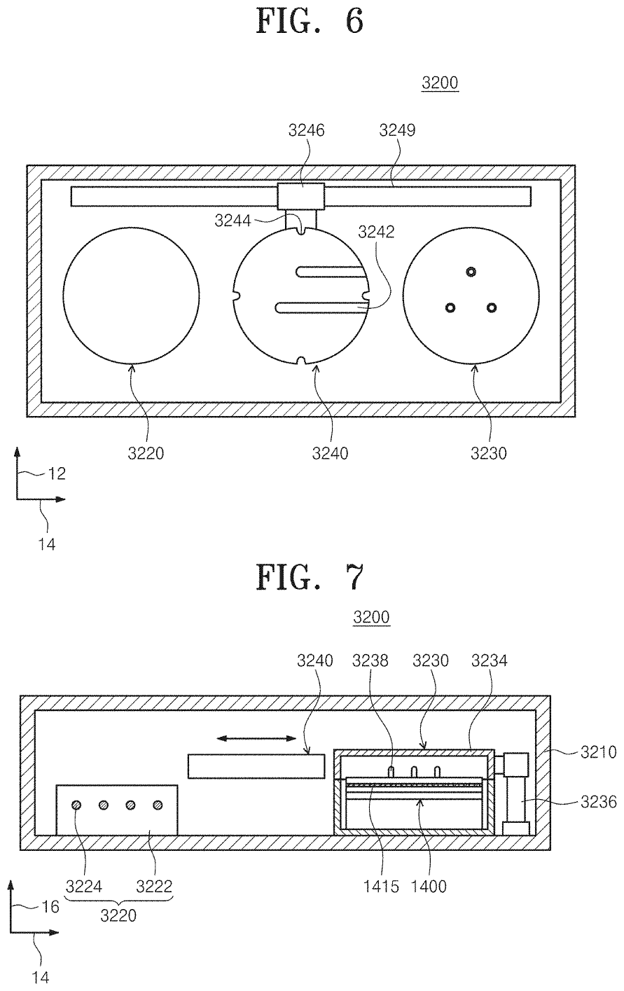

FIG. 6 is a schematic horizontal sectional view illustrating one example of the heat treatment chambers of FIG. 4, and FIG. 7 is a front sectional view illustrating the heat treatment chamber of FIG. 6. The heat treatment chamber 3200 includes a housing 3210, a cooling unit 3220, a heating unit 3230, and a transfer plate 3240.

The housing 3210 has a substantially rectangular parallelepiped shape. The housing 3210 has, in a sidewall thereof, an entrance/exit opening (not illustrated) through which a substrate W enters and exits the housing 3210. The entrance/exit opening may remain open. A door (not illustrated) may be provided to selectively open and close the entrance/exit opening. The cooling unit 3220, the heating unit 3230, and the transfer plate 3240 are provided in the housing 3210. The cooling unit 3220 and the heating unit 3230 are provided side by side in the Y-axis direction 14. According to an embodiment, the cooling unit 3220 may be located closer to the transfer chamber 3400 than the heating unit 3230.

The cooling unit 3220 includes a cooling plate 3222. The cooling plate 3222 may have a substantially circular shape when viewed from above. A cooling member 3224 is provided inside the cooling plate 3222. According to an embodiment, the cooling member 3224 may be formed inside the cooling plate 3222 and may serve as a fluid channel through which a cooling fluid flows.

The heating unit 3230 includes a heating member 1400 and a cover 3234. The heating member 1400 has a substantially circular shape when viewed from above. The heating member 1400 has a larger diameter than the substrate W. The heating member 1400 includes heating elements 1415. The heating elements 1415 may be resistance heating elements to which electric current is applied.

The heating member 1400 includes lift pins 3238 that are vertically movable in the Z-axis direction 16. The lift pins 3238 receive the substrate W from a transfer unit outside the heating unit 3230 and lay the substrate W down on the heating member 1400, or raise the substrate W off the heating member 1400 and transfer the substrate W to the transfer unit outside the heating unit 3230. According to an embodiment, three lift pins 3238 may be provided. The cover 3234 includes a space therein, which is open at the bottom. The cover 3234 is located over the heating member 1400 and is vertically moved by an actuator 3236. When the cover 3234 is brought into contact with the heating member 1400, the space surrounded by the cover 3234 and the heating member 1400 serves as a heating space in which the substrate W is heated.

The transfer plate 3240 has a substantially circular plate shape and has a diameter corresponding to that of the substrate W. The transfer plate 3240 has notches 3244 formed at the edge thereof. The notches 3244 may have a shape corresponding to the support protrusions 3429 formed on the hand A of the transfer unit 3420 described above. Furthermore, as many notches 3244 as the support protrusions 3429 of the hand A are formed in positions corresponding to the support protrusions 3429. The substrate W is transferred between the hand A and the transfer plate 3240 when the vertical positions of the hand A and the transfer plate 3240 aligned with each other in the vertical direction are changed. The transfer plate 3240 is mounted on a guide rail 3249 and moved along the guide rail 3249 by an actuator 3246. The transfer plate 3240 includes a plurality of guide grooves 3242 having a slit shape. The guide grooves 3242 extend inward from the edge of the transfer plate 3240. The lengthwise direction of the guide grooves 3242 is parallel to the Y-axis direction 14, and the guide grooves 3242 are spaced apart from each other in the X-axis direction 12. The guide grooves 3242 prevent interference between the transfer plate 3240 and the lift pins 3238 when the substrate W is transferred between the transfer plate 3240 and the heating unit 3230.

The substrate W is heated in the state in which the substrate W is directly placed on the heating member 1400. The substrate W is cooled in the state in which the transfer plate 3240 having the substrate W placed thereon is brought into contact with the cooling plate 3222. The transfer plate 3240 is formed of a material having a high heat transfer rate for efficient heat transfer between the cooling plate 3222 and the substrate W. According to an embodiment, the transfer plate 3240 may be formed of a metallic material.

Heating units 3230 provided in some of the heat treatment chambers 3200 may improve adhesion of photoresist to the substrate W by supplying a gas while heating the substrate W. According to an embodiment, the gas may be a hexamethyldisilane gas.

Hereinafter, the heating member 1400 according to an embodiment of the inventive concept will be described in detail.

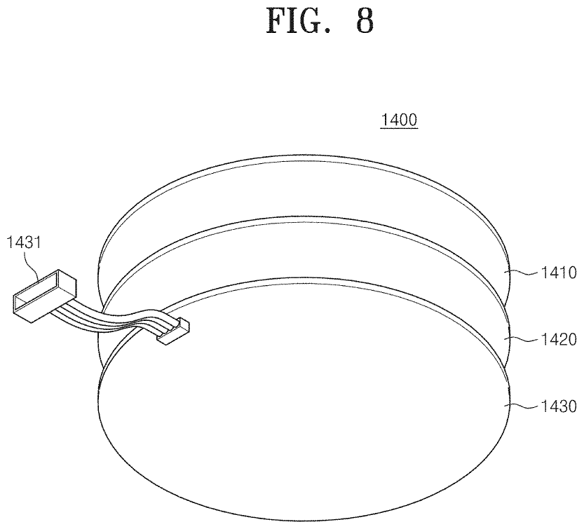

FIG. 8 is an exploded perspective view of the heating member 1400 according to an embodiment of the inventive concept.

The heating member 1400 includes a heater plate 1410, a connecting plate 1420, and a control plate 1430. The connecting plate 1420 is disposed under the heater plate 1410. The control plate 1430 is disposed under the connecting plate 1420.

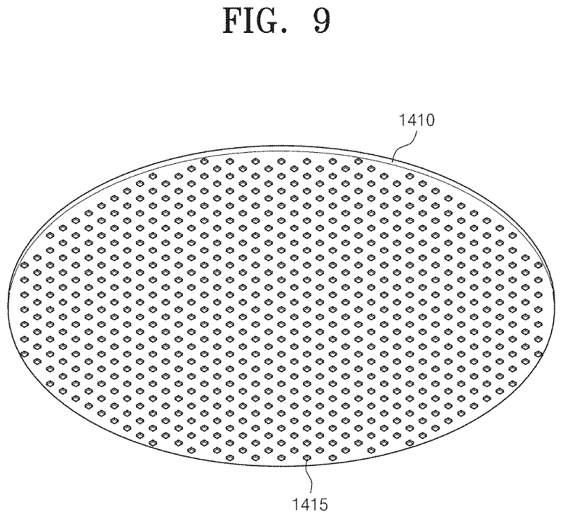

FIG. 9 is a bottom view of the heater plate 1410 according to an embodiment of the inventive concept. The heating elements 1415 are bonded to the bottom of the heater plate 1410. The heater plate 1410 is formed of a material having a high thermal conductivity. In an embodiment, the heater plate 1410 may be formed of a metallic material. The heating elements 1415 may be scaled as needed, and as many heating elements 1415 as necessary may be provided.

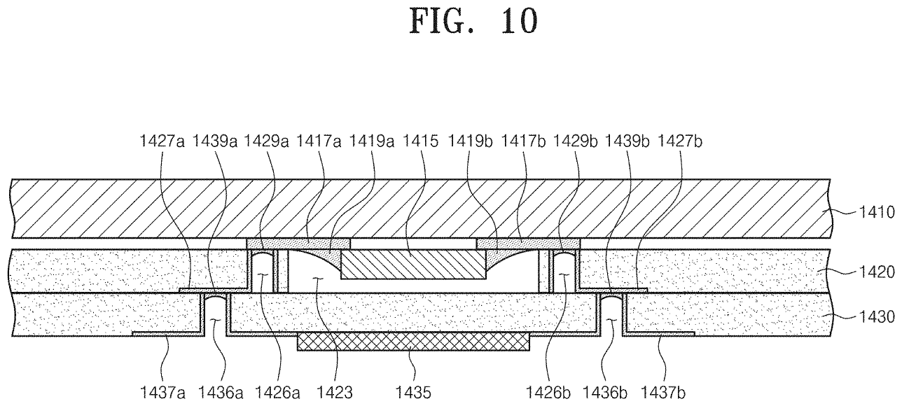

FIG. 10 is an enlarged sectional view illustrating a portion in which a heating element 1415 is provided in the heating member 1400 according to an embodiment of the inventive concept. The heating member 1400 will be described in more detail with reference to FIG. 10.

The heater plate 1410 includes a first metal pad 1417a and a second metal pad 1417b. The heating element 1415 is bonded to the first metal pad 1417a and the second metal pad 1417b. The heating element 1415 and the first metal pad 1417a are bonded by soldering 1417a. The heating element 1415 and the second metal pad 1417b are bonded by soldering 1417b.

In an embodiment, the connecting plate 1420 is implemented with a PCB. The connecting plate 1420 has a first space 1423 formed therein in which the heating element 1415 is accommodated. A plurality of first spaces 1423 may be formed. Heating elements 1415 may be accommodated in the first spaces 1423, respectively. The connecting plate 1420 has a first via hole 1426a and a second via hole 1426b formed around the first space 1423. The first via hole 1426a is connected with the first metal pad 1417a. The second via hole 1426b is connected with the second metal pad 1417b. The connecting plate 1420 includes a first circuit pattern 1427a and a second circuit pattern 1427b formed on one surface thereof. A metallic material partially or entirely fills the first via hole 1426a such that the first metal pad 1417a and the first circuit pattern 1427a are electrically connected. A metallic material partially or entirely fills the second via hole 1426b such that the second metal pad 1417b and the second circuit pattern 1427b are electrically connected.

In an embodiment, the control plate 1430 is implemented with a PCB. The control plate 1430 includes a control element 1435. The control element 1435 controls the heating element 1415. The control element 1435 is electrically connected with a third circuit pattern 1437a and a fourth circuit pattern 1437b that are formed on one surface of the control plate 1430. In an embodiment, the third circuit pattern 1437a may be connected to a positive (+) electrode of the heating element 1415. The fourth circuit pattern 1437b may be connected to a negative (−) electrode of the heating element 1415. The control plate 1430 has a third via hole 1436a and a fourth via hole 1436b formed therein. The third via hole 1436a is formed in a position corresponding to the first circuit pattern 1427a. The third via hole 1436a is connected with the first circuit pattern 1427a. The fourth via hole 1436b is formed in a position corresponding to the second circuit pattern 1427b. The fourth via hole 1436b is connected with the second circuit pattern 1427b. A metallic material partially or entirely fills the third via hole 1436a such that the first circuit pattern 1427a and the third circuit pattern 1437a are electrically connected. A metallic material partially or entirely fills the fourth via hole 1436b such that the second circuit pattern 1427b and the fourth circuit pattern 1437b are electrically connected. The control plate 1430 is spaced apart from the heating element 1415 by a predetermined gap. The control element 1435 and the heating element 1415 are electrically connected.

In an embodiment, as many control elements 1435 as the heating elements 1415 may be provided. The control elements 1435 may control the heating elements 1415, respectively. In another embodiment, a control element 1435 electrically connected with a plurality of heating elements 1415 provided in each region may be provided. The control element 1435 may control the plurality of heating elements 1415 provided in each region. The control element 1435 may be electrically connected with a connector 1431 and may receive an electrical signal from the outside.

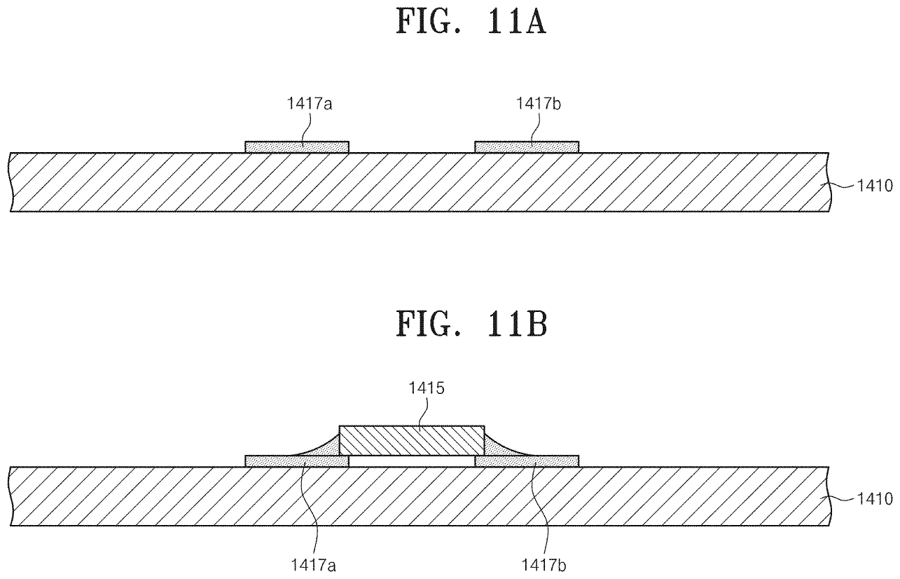

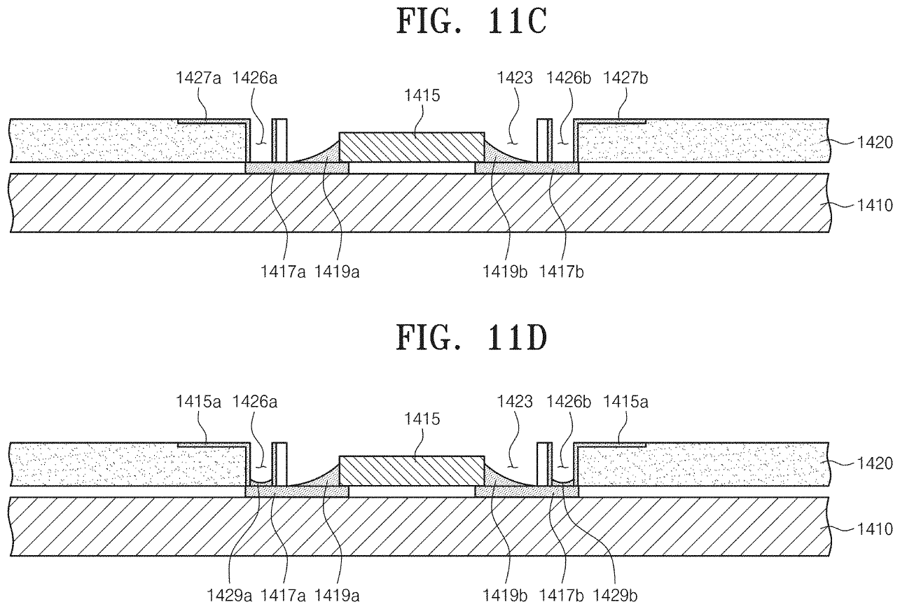

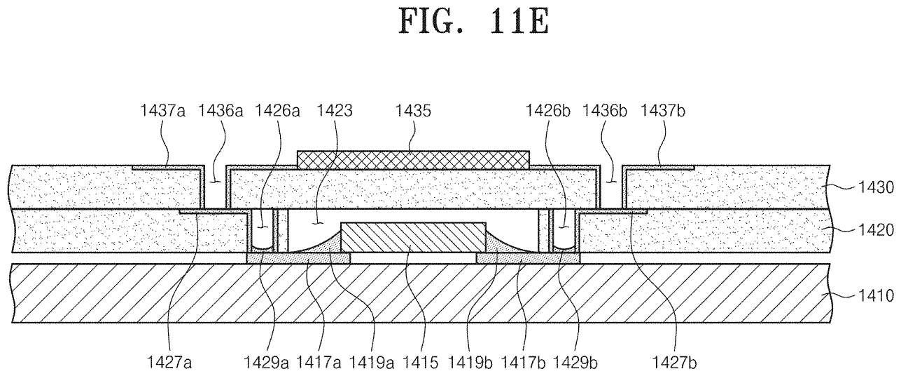

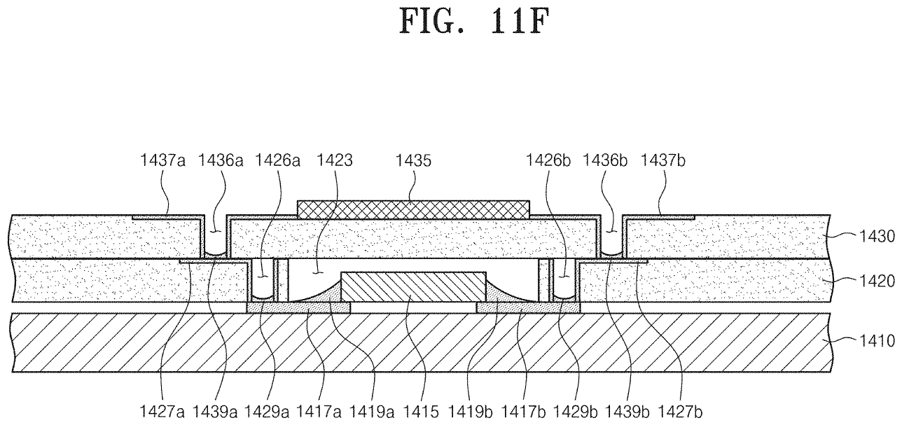

FIGS. 11A to 11F are views illustrating an assembly sequence of the heating member 1400 according to an embodiment of the inventive concept. A method of assembling the heating member 1400 will be described with reference to FIGS. 11A to 11F in sequence.

Referring to FIG. 11A, the heater plate 1410 is prepared. The heater plate 1410 includes the first metal pad 1417a and the second metal pad 1417b bonded thereto.

Referring to FIG. 11B, the heating element 1415 is soldered onto the first metal pad 1417a and the second metal pad 1417b of the heater plate 1410.

Referring to FIG. 11C, the connecting plate 1420 is prepared. The connecting plate 1420 includes the first circuit pattern 1427a and the second circuit pattern 1427b printed thereon. The heating element 1415 is accommodated in the first space 1423 of the connecting plate 1420. The first via hole 1426a is located on the first metal pad 1417a. The second via hole 1426b is located on the second metal pad 1417b.

Referring to FIG. 11D, a metal paste or a metal ball is inserted into the first via hole 1426a and the second via hole 1426b, and soldering is performed by heating the metal paste or the metal ball. The first circuit pattern 1427a and the first metal pad 1417a are electrically connected by first soldering 1429a. The second circuit pattern 1427b and the second metal pad 1417b are electrically connected by second soldering 1429b.

Referring to FIG. 11E, the control plate 1430 is prepared. The control plate 1430 includes the control element 1435 bonded thereto. The control plate 1430 includes the third circuit pattern 1437a and the fourth circuit pattern 1437b printed thereon. The third via hole 1436a is located on the first circuit pattern 1427a. The fourth via hole 1436b is located on the second circuit pattern 1427b.

Referring to FIG. 11F, a metal paste or a metal ball is inserted into the third via hole 1436a and the fourth via hole 1436b, and soldering is performed by heating the metal paste or the metal ball. The first circuit pattern 1427a and the third circuit pattern 1437a are electrically connected by third soldering 1439a. The second circuit pattern 1427b and the fourth circuit pattern 1437b are electrically connected by fourth soldering 1439b.

The above-described soldering may be performed by an automatic mounting machine.

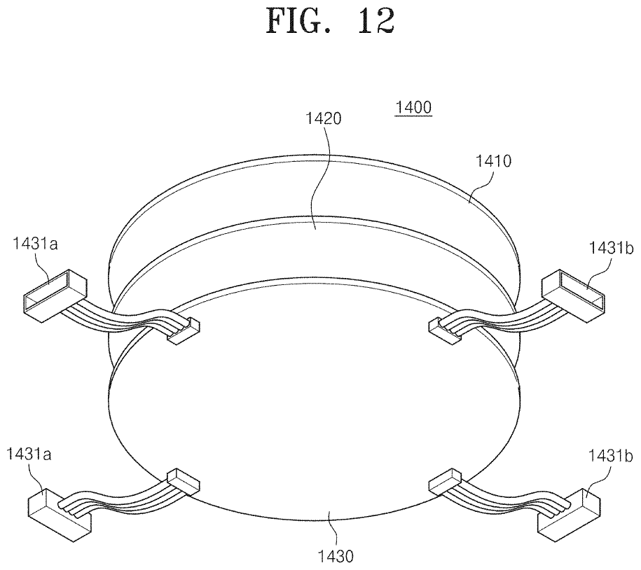

FIG. 12 is an exploded perspective view of a heating unit including a control plate according to another embodiment of the inventive concept. If the number of control elements 1435 is increased as a heating zone is divided, all printed circuits may not be able to be drawn with only one connector provided on one side. Accordingly, a plurality of connectors 1431a, 1431b, 1431c, and 1431d may be provided, control elements 1435 may be separately provided for respective regions, for example, four regions, and printed circuits connected with the connectors 1431a, 1431b, 1431c, and 1431d corresponding to the respective regions may be configured.

According to the embodiments of the inventive concept, the heating element 1415 is directly attached to the bottom of the heater plate 1410, and thus the area by which the heating element 1415 makes contact with a PCB, such as the connecting plate 1420 and the control plate 1430, is minimized. Accordingly, heat conduction to the PCB may be decreased, and heat conduction to the heater plate 410 may be increased.

According to the embodiments of the inventive concept, the heating element 1415 and the control element 1435 are electrically connected through the first via hole 1426a and the second via hole 1426b of the connecting plate 1420, and thus connecting elements, such as electric wires, pins, and other connectors, are not required.

According to the embodiments of the inventive concept, the heating element 1415 exists between the heater plate 1410 and the control plate 1430, and thus heat loss due to an air flow may be prevented.

According to the embodiments of the inventive concept, the heating member 1400 has no electric wire, and thus many heating zones may be used depending on the size of the heating element 1415. As the number of controllable heating zones is increased, the number of points at which the temperature of the heater plate 1410 is able to be controlled increases, which is advantageous for temperature control.

According to the embodiments of the inventive concept, the bottom surface of the heating member 1440 maintains a predetermined shape, and thus there is little change in convection flow due to the shape of an electric wire.

According to the embodiments of the inventive concept, in a method using a heating wire, a resistance deviation of 10% or less occurs depending on the thickness or shape, whereas the heating element 1415 is implemented with a chip so that a resistance deviation of 1% or less occurs. Accordingly, high precision may be achieved.

The embodiment of the substrate treating apparatus 1 has been described above. In the range including the corresponding components, the detailed structure of the substrate treating apparatus 1 may be changed within a range that can be easily changed by those skilled in the art.

According to the embodiments of the inventive concept, the heating member and the substrate treating apparatus may efficiently treat a substrate.

According to the embodiments of the inventive concept, the heating member and the substrate treating apparatus may precisely control a heating temperature of a substrate.

According to the embodiments of the inventive concept, the heating member and the substrate treating apparatus may increase a heating zone, compared to those in the related art.

According to the embodiments of the inventive concept, by removing electric wires under the heating member, the heating member and the substrate treating apparatus may make air convection under the heating member uniform, may reduce a difference in temperature between regions, and may solve a problem of stress in joints of the electric wires.

Effects of the inventive concept are not limited to the above-described effects. Any other effects not mentioned herein may be clearly understood from this specification and the accompanying drawings by those skilled in the art to which the inventive concept pertains.

Although the embodiments of the inventive concept have been described above, it should be understood that the embodiments are provided to help with comprehension of the inventive concept and are not intended to limit the scope of the inventive concept and that various modifications and equivalent embodiments can be made without departing from the spirit and scope of the inventive concept. The drawings provided in the inventive concept are only drawings of the optimal embodiments of the inventive concept. The scope of the inventive concept should be determined by the technical idea of the claims, and it should be understood that the scope of the inventive concept is not limited to the literal description of the claims, but actually extends to the category of equivalents of technical value.

While the inventive concept has been described with reference to embodiments, it will be apparent to those skilled in the art that various changes and modifications may be made without departing from the spirit and scope of the inventive concept. Therefore, it should be understood that the above embodiments are not limiting, but illustrative.

What is claimed is:

1. A heating member comprising:
a heater plate having at least one heating element bonded thereto;
a connecting plate having a first space formed therein in which the heating element is accommodated; and
a control plate having a control element bonded thereto, the control element being electrically connected with the heating element and configured to control the heating element.

2. The heating member of claim 1, wherein the heating element is bonded with a first metal pad and a second metal pad bonded to the heater plate.

3. The heating member of claim 2, wherein the connecting plate has a first via hole and a second via hole formed around the first space.

4. The heating member of claim 3, wherein the first via hole is connected with the first metal pad, and
wherein the second via hole is connected with the second metal pad.

5. The heating member of claim 4, wherein the connecting plate includes:
a first circuit pattern electrically connected with a metallic material provided in the first via hole; and
a second circuit pattern electrically connected with a metallic material provided in the second via hole.

6. The heating member of claim 5, wherein in the control plate, a third via hole is formed in a position corresponding to the first circuit pattern, and a fourth via hole is formed in a position corresponding to the second circuit pattern.

7. The heating member of claim 6, wherein the control plate includes:
a third circuit pattern electrically connected with a metallic material provided in the third via hole; and
a fourth circuit pattern electrically connected with a metallic material provided in the fourth via hole, and
wherein the third circuit pattern and the fourth circuit pattern are electrically connected with the control element.

8. The heating member of claim 1, wherein the heating element is spaced apart from the control plate.

9. The heating member of claim 1, wherein the first space includes a plurality of first spaces,
wherein the heating element includes a plurality of heating elements, and
wherein the plurality of heating elements are accommodated in the plurality of first spaces, respectively.

10. The heating member of claim 1, wherein the control element includes a plurality of control elements,
wherein the heating element includes a plurality of heating elements, and
wherein each of the control elements is electrically connected with some of the plurality of heating elements.

11. The heating member of claim 1, wherein the control element includes a plurality of control elements,
wherein the heating element includes a plurality of heating elements, and
wherein the plurality of control elements are electrically connected with the plurality of heating elements, respectively.

12. A substrate treating apparatus comprising:
a chamber having a process space therein;
a support unit configured to support a substrate in the process space; and
a heating member provided in the support unit and configured to heat the substrate,
wherein the heating member includes:
a heater plate having at least one heating element bonded thereto;
a connecting plate having a first space formed therein in which the heating element is accommodated; and
a control plate having a control element bonded thereto, the control element being electrically connected with the heating element and configured to control the heating element.

13. The substrate treating apparatus of claim 12, wherein the heating element is bonded with a first metal pad and a second metal pad bonded to the heater plate.

14. The substrate treating apparatus of claim 13, wherein the connecting plate has a first via hole and a second via hole formed around the first space,
wherein the first via hole is connected with the first metal pad, and
wherein the second via hole is connected with the second metal pad.

15. The substrate treating apparatus of claim 14, wherein the connecting plate includes:
a first circuit pattern electrically connected with a metallic material provided in the first via hole; and
a second circuit pattern electrically connected with a metallic material provided in the second via hole.

16. The substrate treating apparatus of claim 15, wherein in the control plate, a third via hole is formed in a position corresponding to the first circuit pattern, and a fourth via hole is formed in a position corresponding to the second circuit pattern.

17. The substrate treating apparatus of claim 16, wherein the control plate includes:
a third circuit pattern electrically connected with a metallic material provided in the third via hole; and
a fourth circuit pattern electrically connected with a metallic material provided in the fourth via hole, and
wherein the third circuit pattern and the fourth circuit pattern are electrically connected with the control element.

18. The substrate treating apparatus of claim 12, wherein the heating element is spaced apart from the control plate.

19. The substrate treating apparatus of claim 12, wherein the first space includes a plurality of first spaces,
wherein the heating element includes a plurality of heating elements, and
wherein the plurality of heating elements are accommodated in the plurality of first spaces, respectively.

20. A substrate treating apparatus comprising:
a chamber having a process space therein;
a support unit configured to support a substrate in the process space; and
a heating member provided in the support unit and configured to heat the substrate,
wherein the heating member includes:
a heater plate including a plurality of heating elements, each of which is bonded to the heater plate through a first metal pad and a second metal pad;
a connecting plate in which a first via hole connected with the first metal pad and a second via hole connected with the second metal pad are formed, the connecting plate including a first circuit pattern electrically connected with a metallic material provided in the first via hole and a second circuit pattern electrically connected with a metallic material provided in the second via hole, wherein as many first spaces as the plurality of heating elements are formed in the connecting plate, and the heating elements are accommodated in the first spaces, respectively; and
a control plate in which a third via hole is formed in a position corresponding to the first circuit pattern and a fourth via hole is formed in a position corresponding to the second circuit pattern, the control plate including a third circuit pattern electrically connected with a metallic material provided in the third via hole and a fourth circuit pattern electrically connected with a metallic material provided in the fourth via hole, wherein the control plate has a plurality of control elements bonded thereto, each of which is electrically connected with the third circuit pattern and the fourth circuit pattern and controls a corresponding one of the heating elements.
